(19) United States
(12) Patent Application Publication
(10) Pub. No.: US 2015/0318259 A1
(43) Pub. Date: Nov. 5, 2015

(54) INTEGRATED CIRCUIT PACKAGING SYSTEM WITH NO-REFLOW CONNECTION AND METHOD OF MANUFACTURE THEREOF

(71) Applicants: KyungOe Kim, Daejeon (KR); Seong Won Park, Icheon-si (KR); MinJung Kim, Kwang-ju-city (KR); ChangHwan Kim, Cheonan-si (KR); ByungHyun Kwak, Icheon-si (KR); WanIl Lee, Seoul (KR)

(72) Inventors: KyungOe Kim, Daejeon (KR); Seong Won Park, Icheon-si (KR); MinJung Kim, Kwang-ju-city (KR); ChangHwan Kim, Cheonan-si (KR); ByungHyun Kwak, Icheon-si (KR); WanIl Lee, Seoul (KR)

(21) Appl. No.: 14/696,741

(22) Filed: Apr. 27, 2015

Related U.S. Application Data
(60) Provisional application No. 61/987,708, filed on May 2, 2014.

(51) Int. Cl. H01L 23/00; H01L 23/31; H01L 23/498; H01L 21/56

(52) U.S. Cl. CPC H01L 24/81; H01L 21/563; H01L 24/17; H01L 23/3142; H01L 23/49838; H01L 2924/14; H01L 2224/81801; H01L 2224/16238; H01L 2224/16113; H01L 2224/16057

(57) ABSTRACT

An integrated circuit packaging system, and a method of manufacture thereof, includes: an integrated circuit; a substrate having a substrate contact; an internal interconnect between the substrate and the integrated circuit, the internal interconnect is a no-reflow connection directly on the substrate contact and the integrated circuit; and an encapsulation over the internal interconnect.

### CROSS-REFERENCE TO RELATED APPLICATION(S)

This application claims the benefit of U.S. Provisional Patent Application Ser. No. 61/987,708 filed May 2, 2014, and the subject matter thereof is incorporated herein by reference thereto.

### TECHNICAL FIELD

The present invention relates generally to an integrated circuit packaging system, and more particularly to a system for die to substrate solder connections.

### BACKGROUND ART

The current mass reflow process used in electrically connecting integrated circuit die to substrates allows high units per hour (UPH) production, but there is an under bump metallurgy (UBM) size limitation. When a bump pitch or distance between the connections becomes too small, the quality of the units decreases.

Another process, thermal compression or thermocompression (TC) bonding, using non-conductive paste (NCP) underfill process, allows fine bump pitch, but the process does not meet high UPH production requirements and has bonding quality problems. The bonding quality problems include poor solder joint shape, NCP traps or voids, etc.

Thus, a need still remains for integrated circuit packaging capable of meeting high UPH production requirements with fine bump pitch, high quality solder joints, and reduced traps. In view of these requirements, it is increasingly critical that answers be found to these problems.

In view of the ever-increasing commercial competitive pressures, along with growing consumer expectations and the diminishing opportunities for meaningful product differentiation in the marketplace, it is critical that answers be found for these problems.

Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

Embodiments of the present invention provide a method of manufacture of an integrated circuit packaging system that includes providing an integrated circuit; providing a substrate having a substrate contact; forming an internal interconnect between the substrate and the integrated circuit, the internal interconnect is a no-reflow connection directly on the substrate contact and the integrated circuit; and forming an encapsulation over the internal interconnect.

The embodiments of the present invention provide an integrated circuit packaging system that includes an integrated circuit; a substrate having a substrate contact; an internal interconnect between the substrate and the integrated circuit, the internal interconnect is a no-reflow connection directly on the substrate contact and the integrated circuit; and an encapsulation over the internal interconnect.

Certain embodiments of the invention have other steps or elements in addition to or in place of those mentioned above. The steps or the elements will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system taken along line 1-1 of FIG. 2 in an embodiment of the present invention.

FIG. 2 is a top view of the integrated circuit packaging system.

FIG. 3A is an example of the device connectors as bump on lead (BOL) type connectors without elongation.

FIG. 3B is another example of the device connectors as bump on lead (BOL) type connectors with the elongation.

FIG. 4A is an example of the device connectors as embedded trace substrate (ETS) type connectors without the elongation.

FIG. 4B is another example of the device connectors as embedded trace substrate (ETS) type connectors with the elongation.

FIG. 5A is an example of the internal interconnects as bump type connectors without the elongation.

FIG. 5B is another example of the internal interconnects as bump type connectors with the elongation.

FIG. 6 is a cross-sectional view of a portion of the integrated circuit packaging system of FIG. 1 in a depositing flux step of the process flow.

FIG. 7 is a cross-sectional view of a portion of the integrated circuit packaging system of FIG. 1 in a die pickup step of the process flow.

FIG. 8 is the structure of FIG. 7 in a bonding head heating step.

FIG. 9 is the structure of FIG. 8 in a bonding step.

FIG. 10 is the structure of FIG. 9 in an elongation step.

FIG. 11 is the structure of FIG. 10 in a bonding head cooling step.

FIG. 12 is the structure of FIG. 11 in a bonding head removal step.

FIG. 13 is the structure of FIG. 12 in a de-fluxing step.

FIG. 14 is the structure of FIG. 13 in an underfilling step.

FIG. 15 is a flow chart of the process flow described above.

FIG. 16 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGS. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to a plane of a surface of a support structure, which will subsequently be described as a substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is contact between elements. The term “directly on” means that there is direct physical contact between one element and another element without an intervening element.

The term “processing” as used herein includes deposition of material or photoresist, patterning, exposure, development, etching, cleaning, and/or removal of the material or photoresist as required in forming a described structure.

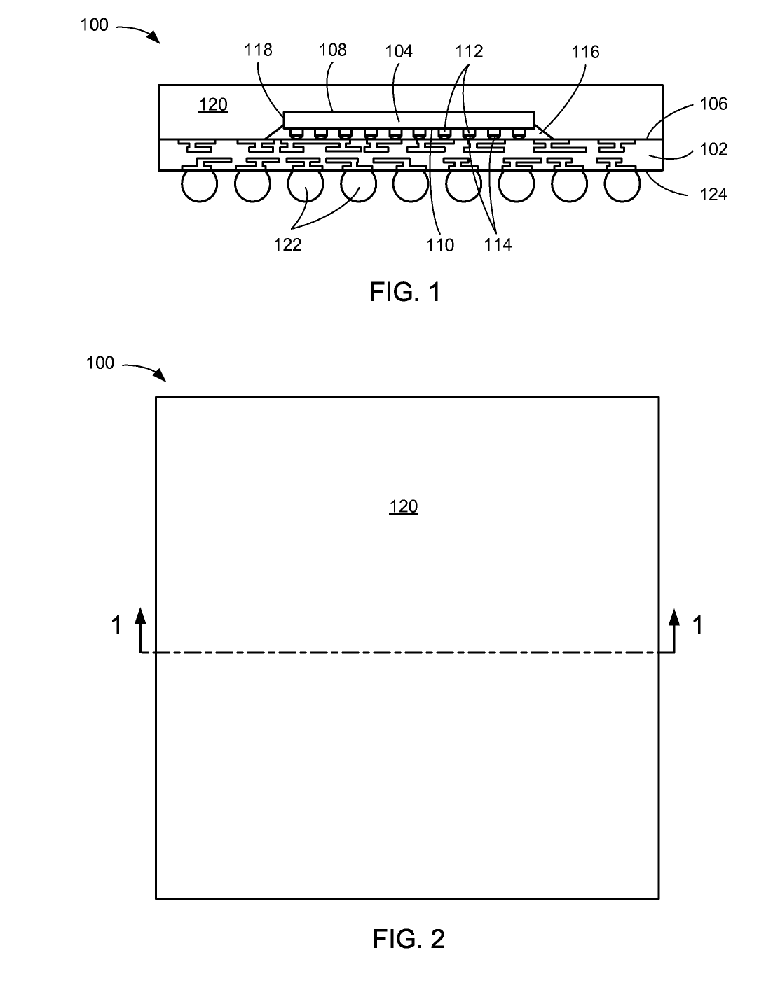

Referring now to FIG. 1, therein is shown a cross-sectional view of an integrated circuit packaging system 100 taken along line 1-1 of FIG. 2 in an embodiment of the present invention. The integrated circuit packaging system 100 includes a package structure having a substrate 102 and an integrated circuit 104 mounted over a substrate top side 106 of the substrate 102.

The integrated circuit 104 includes an inactive side 108 and an active side 110 opposite to the inactive side 108. For example, the integrated circuit 104 can represent a circuit device including an integrated circuit die or a flip-chip.

The integrated circuit 104 is a circuit device having a number of integrated transistors interconnected to form active circuits. The active side 110 is a side of the integrated circuit 104 having active circuitry fabricated thereon or having elements for connection to the active circuitry of the integrated circuit 104.

The integrated circuit 104 includes device connectors 112 at the active side 110. The device connectors 112 are attached to the substrate top side 106 by internal interconnects 114 with the active side 110 facing the substrate top side 106. The integrated circuit packaging system 100 optionally includes an underfill 116. For example, the underfill 116 can represent a capillary underfill or a molded underfill.

The internal interconnects 114 are no-reflow connections between the device connectors 112 and the substrate 102. Each of the no-reflow connections includes a structure that is formed by thermocompression bonding without requiring a solder reflow process. For example, the internal interconnects 114 can represent no-reflow solder connections.

Cooling speeds of the internal interconnects 114 formed using the thermocompression bonding can be faster than cooling speeds of solder bumps formed using the mass reflow. Volumes of the internal interconnects 114 formed using in the thermocompression bonding can be less than volumes of solder bumps formed using the mass reflow.

The underfill 116 is formed between the substrate 102 and the integrated circuit 104. The underfill 116 covers the device connectors 112 and the internal interconnects 114 providing protection to the device connectors 112 and the internal interconnects 114. The underfill 116 is attached to or directly on the substrate top side 106 and the active side 110. The underfill 116 is directly on a portion of a device non-horizontal side 118 of the integrated circuit 104.

The integrated circuit packaging system 100 includes an encapsulation 120 over the substrate 102, the integrated circuit 104, and the underfill 116. The encapsulation 120 is a cover of a semiconductor package that hermetically seals a circuit device as well as providing mechanical and environmental protection.

When the underfill 116 is not formed, the encapsulation 120 can be formed between the substrate 102 and the integrated circuit 104 instead of the underfill 116. In this case, the encapsulation 120 can be formed as a molded underfill covering the device connectors 112 and the internal interconnects 114 and attached to or directly on the substrate top side 106 and the active side 110.

The integrated circuit packaging system 100 includes a grid array of external connectors 122. The external connectors 122 can be attached to a substrate bottom side 124 of the substrate 102 opposite to the substrate top side 106. For example, the external connectors 122 can include solder balls or any other electrically conductive connectors.

The embodiments of the present invention provide a new bonding method of assembly package for low cost and high performance that do not require a solder reflow process.

The embodiments of the present invention, described as a molten solder controlled flip chip (MCFC) bonding method, can be defined as new interconnection method through mixing mass reflow (MR) and TC bonding.

It has been found that the device connectors 112 attached to the substrate 102 by the internal interconnects 114 do not require non-conductive paste (NCP) as an adhesive material between the integrated circuit 104 and the substrate 102. As such, these embodiments have a shorter bond time profile than previous processes requiring the non-conductive paste.

It has also been found that the device connectors 112 attached to the substrate 102 by the internal interconnects 114 make it possible to interconnect solder bumps and bond on lead or embedded trace substrate bond pads without requiring a reflow process.

It has further been found that the device connectors 112 attached to the substrate 102 by the internal interconnects 114 allow for finer bump pitch and smaller under bump metallurgy size than a mass reflow process due to elimination of the mass reflow process. Various critical dimensions are described below.

It has further been found that attachment of the device connectors 112 to the substrate 102 provides relatively higher units per hour throughput and requires lower bonding force than processes using thermal-compression bonding with non-conductive paste.

Referring now to FIG. 2, therein is shown a top view of the integrated circuit packaging system 100. The top view depicts the encapsulation 120 as a package cover of the integrated circuit packaging system 100.

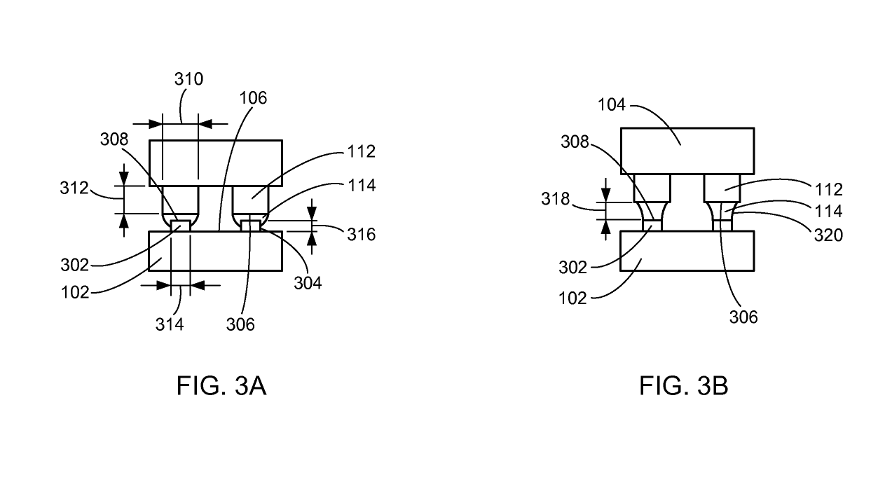

Referring now to FIG. 3A, therein is shown an example of the device connectors 112 as bump on lead (BOL) type connectors without elongation. The device connectors 112 are on substrate contacts 302 of the substrate 102.

For example, the substrate contacts 302 can include trace-like pads or leads on the substrate 102. Also for example, the substrate contacts 302 connect with the device connectors 112 as column bumps, pillars, contact pillars, or contact pads. Further, for example, the substrate contacts 302 and the device connectors 112 can include a conductive material including copper (Cu), any other metallic material, or a metal alloy.

As an example, the internal interconnects 114 can include bumps. As a specific example, the internal interconnects 114 can be formed of an electrically conductive material including solder or any other metallic or metal alloy. As another specific example, the device connectors 112 can include pillars, the substrate contacts 302 can include leads, and the internal interconnects 114 can include solder bumps without elongation bonding the pillars to the leads on the substrate 102.

The internal interconnects 114 are partially and directly on contact non-horizontal sides 304 of the substrate contacts 302. The internal interconnects 114 are completely and directly on device connector bottom sides 306 of the device connectors 112. The internal interconnects 114 are completely and directly on substrate contact top sides 308 of the substrate contacts 302.

The substrate contacts 302 are formed above and on the substrate top side 106. The substrate contacts 302 protrude from the substrate top side 106.

Each of the device connectors 112 includes a device connector width 310 and a device connector height 312. For example, the device connector width 310 can be even less than about 50 micrometers (um). Also for example, the device connector height 312 can be less than 40 um.

Each of the substrate contacts 302 includes a substrate contact width 314 and a substrate contact height 316. For example, the substrate contact width 314 can be under or less than about 17 um. Also for example, the substrate contact height 316 can be under or less than 20 um.

It has been found that the device connectors 112, each of which having the device connector width 310 less than 50 um, further reduce a pitch or a distance between the device connectors 112 without degrading the quality of a number of high units per hour in production.

It has also been found that the device connectors 112, each of which having the device connector height 312 less than 40 um, further reduce a vertical height profile of the integrated circuit packaging system 100 of FIG. 1.

It has further been found that the substrate contacts 302, each of which having a dimension of the substrate contact width 314 under or less than 17 um, further reduce a pitch or a distance between the substrate contacts 302 without degrading the quality of a number of high units per hour in production.

It has further been found that the substrate contacts 302, each of which having a dimension of the substrate contact height 316 under or less than 20 um, further reduce a vertical height profile of the integrated circuit packaging system 100.

It has further been found that the device connectors 112 and the substrate contacts 302 work well when bond pitches become so fine that solder reflow processes can no longer be used.

It has further been found that the internal interconnects 114 partially and directly on the contact non-horizontal sides 304 improve reliability of joints between the device connectors 112 and the substrate 102. The reliability is improved because the contact non-horizontal sides 304 provide additional surface areas for the internal interconnects 114 to form, thereby further strengthening the joints between the device connectors 112 and the substrate 102.

It has further been found that the internal interconnects 114 completely and directly on the device connector bottom sides 306 and the substrate contact top sides 308 improve reliability of joints between the device connectors 112 and the substrate 102. The reliability is improved because the device connector bottom sides 306 and the substrate contact top sides 308 provide at least entire surface areas for the internal interconnects 114 to form, thereby further strengthening the joints between the device connectors 112 and the substrate 102. The entire surface areas are provided using the thermocompression bonding without requiring the solder reflow process.

It has further been found that the substrate contacts 302 above and on the substrate top side 106 improve reliability of joints between the device connectors 112 and the substrate 102. The reliability is improved because the substrate contacts 302 above and on the substrate top side 106 provide the contact non-horizontal sides 304 as additional surface areas for the internal interconnects 114 to form, thereby further strengthening the joints between the device connectors 112 and the substrate 102.

Referring now to FIG. 3B, therein is shown another example of the device connectors 112 as bump on lead (BOL) type connectors with the elongation. The elongation is a process of lengthening or increasing interconnect heights 318 of the internal interconnects 114.

The internal interconnects 114 are vertically elongated or lengthened such that the internal interconnects 114 are only directly on the device connector bottom sides 306 and the substrate contact top sides 308. The internal interconnects 114 include interconnect non-horizontal surfaces 320 that are concave. Since the internal interconnects 114 are vertically elongated, the interconnect heights 318 are greater than the interconnect heights 318 of the internal interconnects 114 of FIG. 3A, which are formed without the elongation.

The integrated circuit 104 includes the device connectors 112 directly on the internal interconnects 114, which are directly on the substrate contacts 302. The internal interconnects 114 are completely in between the device connectors 112 and the substrate contacts 302. The internal interconnects 114 are completely and directly on the device connector bottom sides 306 and the substrate contact top sides 308.

It has been found that the internal interconnects 114 vertically elongated provide fine bump pitches of the internal interconnects 114. The fine bump pitches are provided because the internal interconnects 114 are vertically lengthened such that no additional horizontal spacing is taken up by the internal interconnects 114, resulting finer spacing between the internal interconnects 114.

It has also been found that the internal interconnects 114 completely and directly on the device connector bottom sides 306 and the substrate contact top sides 308 improve reliability of joints between the device connectors 112 and the substrate 102. The reliability is improved because the device connector bottom sides 306 and the substrate contact top sides 308 provide at least the entire surface areas for the internal interconnects 114 to form, thereby further strengthening the joints between the device connectors 112 and the substrate 102.

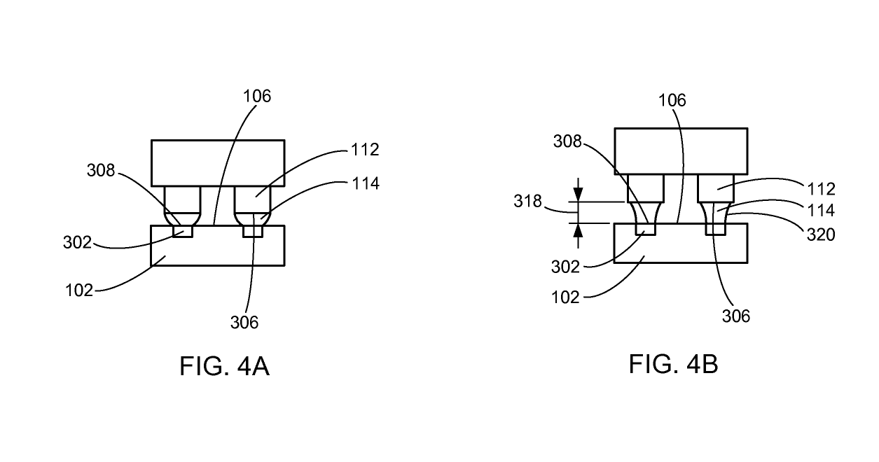

Referring now to FIG. 4A, therein is shown an example of the device connectors 112 as embedded trace substrate (ETS) type connectors without the elongation. The device connectors 112 are on the substrate contacts 302.

The substrate contacts 302 are completely embedded within the substrate 102. The substrate contacts 302 are below the substrate top side 106. The substrate contact top sides 308 and the substrate top side 106 can be coplanar with each other.

The internal interconnects 114 are completely and directly on the device connector bottom sides 306. The internal interconnects 114 are completely and directly on the substrate contact top sides 308. The internal interconnects 114 are partially and directly on the substrate top side 106. The internal interconnects 114 are completely in between the device connectors 112 and the substrate contacts 302.

It has been found that the substrate contacts 302 completely within the substrate 102 and below the substrate top side 106 further reduce a vertical height profile of the integrated circuit packaging system 100 of FIG. 1.

It has also been found that the internal interconnects 114 completely and directly on the device connector bottom sides 306 and the substrate contact top sides 308 improve reliability of joints between the device connectors 112 and the substrate 102. The reliability is improved because the device connector bottom sides 306 and the substrate contact top sides 308 provide at least the entire surface areas for the internal interconnects 114 to form, thereby further strengthening the joints between the device connectors 112 and the substrate 102.

Referring now to FIG. 4B, therein is shown another example of the device connectors 112 as embedded trace substrate (ETS) type connectors with the elongation. The device connectors 112 are on the substrate contacts 302.

The internal interconnects 114 are vertically elongated or lengthened such that the internal interconnects 114 are only directly on the device connector bottom sides 306 and the substrate contact top sides 308. The internal interconnects 114 include the interconnect non-horizontal surfaces 320 that are concave. Since the internal interconnects 114 are vertically elongated, the interconnect heights 318 are greater than the interconnect heights 318 of the internal interconnects 114 of FIG. 4A, which are formed without the elongation.

The substrate contacts 302 are completely embedded within the substrate 102. The substrate contacts 302 are below the substrate top side 106. The substrate contact top sides 308 and the substrate top side 106 can be coplanar with each other.

The internal interconnects 114 are completely and directly on the device connector bottom sides 306. The internal interconnects 114 are completely and directly on the substrate contact top sides 308. The internal interconnects 114 are completely in between the device connectors 112 and the substrate contacts 302.

It has been found that the internal interconnects 114 vertically elongated provide fine bump pitches of the internal interconnects 114. The fine bump pitches are provided because the internal interconnects 114 are vertically lengthened such that no additional horizontal spacing is taken up by the internal interconnects 114, resulting finer spacing between the internal interconnects 114.

It has also been found that the substrate contacts 302 completely within the substrate 102 and below the substrate top side 106 further reduce a vertical height profile of the integrated circuit packaging system 100 of FIG. 1.

It has further been found that the internal interconnects 114 completely and directly on the device connector bottom sides 306 and the substrate contact top sides 308 improve reliability of joints between the device connectors 112 and the substrate 102. The reliability is improved because the device connector bottom sides 306 and the substrate contact top sides 308 provide at least the entire surface areas for the internal interconnects 114 to form, thereby further strengthening the joints between the device connectors 112 and the substrate 102.

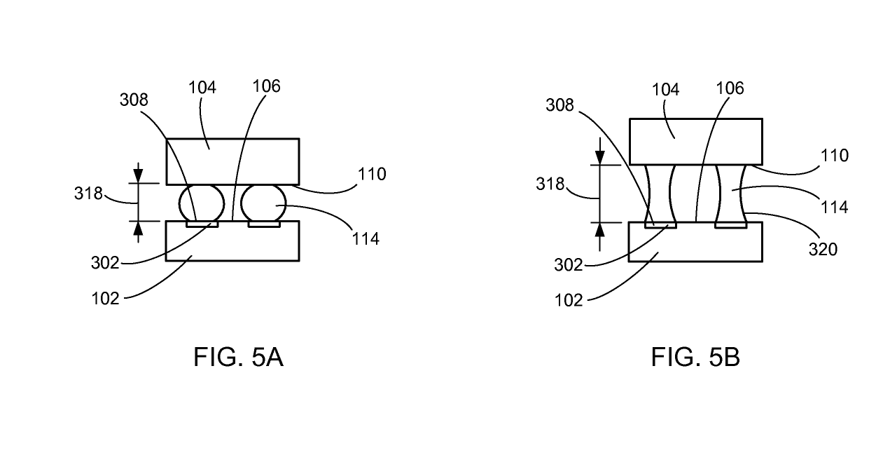

Referring now to FIG. 5A, therein is shown an example of the internal interconnects 114 as bump type connectors without the elongation. The internal interconnects 114 are directly on the substrate contacts 302 and the integrated circuit 104. The internal interconnects 114 include curve surfaces.

The substrate contacts 302 are completely embedded within the substrate 102. The substrate contacts 302 are below the substrate top side 106. The substrate contact top sides 308 and the substrate top side 106 can be coplanar with each other.

The internal interconnects 114 are completely and directly on the substrate contact top sides 308. The internal interconnects 114 are in between the active side 110 and the substrate top side 106. The interconnect heights 318 of the internal interconnects 114 are under or less than 100 um without the elongation.

It has been found that the substrate contacts 302 completely within the substrate 102 and below the substrate top side 106 further reduce a vertical height profile of the integrated circuit packaging system 100 of FIG. 1.

It has also been found that the internal interconnects 114 completely and directly on the substrate contact top sides 308 improve reliability of joints between the integrated circuit 104 and the substrate 102. The reliability is improved because the substrate contact top sides 308 provide at least the entire surface areas for the internal interconnects 114 to form, thereby further strengthening the joints between the integrated circuit 104 and the substrate 102.

It has further been found that the internal interconnects 114 having the interconnect heights 318 less than 100 um without the elongation further reduce a vertical height profile of the integrated circuit packaging system 100.

Referring now to FIG. 5B, therein is shown another example of the internal interconnects 114 as bump type connectors with the elongation. The internal interconnects 114 are directly on the substrate contacts 302.

The internal interconnects 114 are vertically elongated or lengthened such that the internal interconnects 114 are only directly on the substrate contact top sides 308. The internal interconnects 114 include the interconnect non-horizontal surfaces 320 that are concave. Since the internal interconnects 114 are vertically elongated, the interconnect heights 318 are greater than the interconnect heights 318 of the internal interconnects 114 of FIG. 5A, which are formed without the elongation.

The substrate contacts 302 are completely embedded within the substrate 102. The substrate contacts 302 are below the substrate top side 106. The substrate contact top sides 308 and the substrate top side 106 can be coplanar with each other.

The internal interconnects 114 are completely and directly on the substrate contact top sides 308. The internal interconnects 114 are in between the active side 110 and the substrate top side 106. The interconnect heights 318 of the internal interconnects 114 are under or less than 100 um without the elongation.

The embodiments of the present invention can be applied to various bump structures. For example, the bump structures can be formed by the use of solder or any other conductive material including a metallic material or a metal alloy.

It has been found that the internal interconnects 114 vertically elongated provide fine bump pitches of the internal interconnects 114. The fine bump pitches are provided because the internal interconnects 114 are vertically lengthened such that no additional horizontal spacing is taken up by the internal interconnects 114, resulting finer spacing between the internal interconnects 114.

It has also been found that the substrate contacts 302 completely within the substrate 102 and below the substrate top side 106 further reduce a vertical height profile of the integrated circuit packaging system 100 of FIG. 1.

It has further been found that the internal interconnects 114 completely and directly on the substrate contact top sides 308 improve reliability of joints between the integrated circuit 104 and the substrate 102. The reliability is improved because the substrate contact top sides 308 provide at least the entire surface areas for the internal interconnects 114 to form, thereby further strengthening the joints between the integrated circuit 104 and the substrate 102.

It has further been found that the internal interconnects 114 having the interconnect heights 318 less than 100 um without the elongation, further reduce a vertical height profile of the integrated circuit packaging system 100.

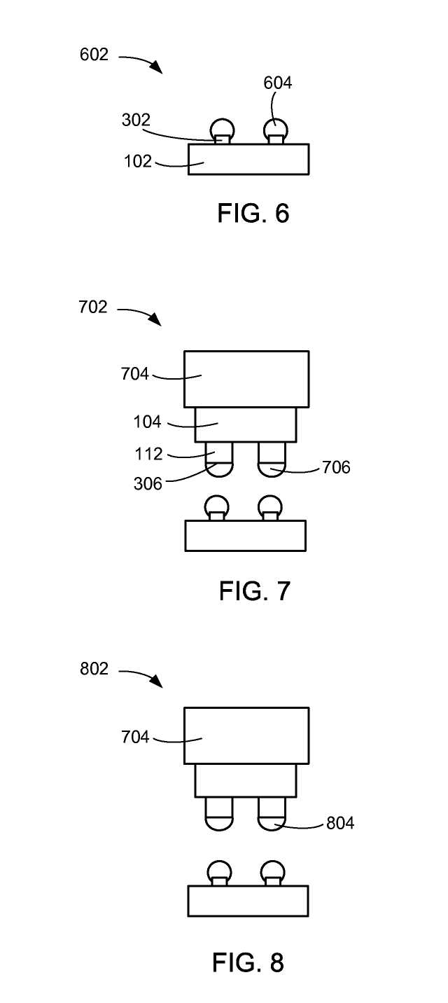

FIGS. 6-14 described below show various steps in a process flow of the embodiments of the present invention. For exemplary purposes, the process flow for the bump on lead type connectors is shown, but the process flow would be the same for the embedded trace substrate type connectors and the bump type connectors.

Referring now to FIG. 6, therein is shown a cross-sectional view of a portion of the integrated circuit packaging system 100 of FIG. 1 in a depositing flux step 602 of the process flow. The depositing flux step can include a flux printing method. The substrate 102 includes the substrate contacts 302 with a flux 604 deposited on the substrate contacts 302. The flux 604 is used to remove oxides during a soldering process.

It has been found that a flux cleaning step may be removed from the process flow when a non-cleaning flux or a flux that does not require cleaning is used. The non-cleaning flux is available from companies, such as the Henkel Corporation of Irvine, Calif. It has also been found that epoxy fluxes have the non-cleaning capability.

Referring now to FIG. 7, therein is shown a cross-sectional view of a portion of the integrated circuit packaging system 100 of FIG. 1 in a die pickup step 702 of the process flow. A bonding head 704 picks up the integrated circuit 104 having the device connectors 112 with a solid conductive material 706 on the device connector bottom sides 306. For example, the solid conductive material 706 can include solder, any electrically conductive material, a metallic material, or a metal alloy.

Referring now to FIG. 8, therein is shown the structure of FIG. 7 in a bonding head heating step 802. The bonding head heating step can include a bonding head ramp-up method. The bonding head 704 is heated to cause the solid conductive material 706 of FIG. 7 to become molten to form a molten conductive material 804. The molten conductive material 804 subsequently enters its solidus state.

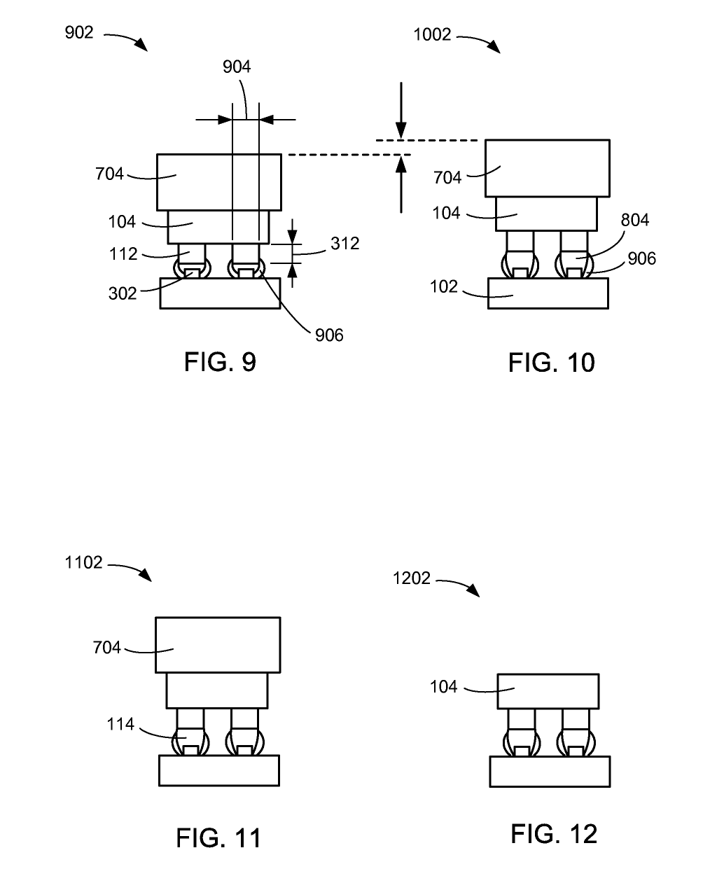

Referring now to FIG. 9, therein is shown the structure of FIG. 8 in a bonding step 902. The bonding step includes a thermal compression bonding process used where the bonding head 704 applies force to the device connectors 112 through the integrated circuit 104.

For example, the device connectors 112 are made of copper (Cu), gold (Au), and aluminum (Al) due to their high diffusion rates. In addition, aluminum and copper are relatively soft metals and have good ductile properties.

Bonding with aluminum or copper can require temperatures ≧400° C. A lower temperature around 300° C. can be used for bonding with gold. Compared to aluminum or copper, gold does not form an oxide so a cleaning procedure can be avoided before bonding

It has been found that the device connectors 112 having dimensions of the device connector height 312 below 25 um and a device connector diameter 904 of each of the device connectors 112 below 30 um are possible with the embodiments of the present invention.

It has also been found in the embodiments of the present invention that a very light force, under 10 newtons, can be applied through the bonding head 704 and a good bond can still be obtained.

The molten conductive material 804 of FIG. 8 engages the substrate contacts 302 of FIG. 6 through the flux 604 of FIG. 6 and bonds the device connectors 112 to the substrate contacts 302. A residual flux 906 remains on the molten conductive material 804 when the non-cleaning flux is not used.

Referring now to FIG. 10, therein is shown the structure of FIG. 9 in an elongation step 1002. The bonding head 704 is moved upward in the z-direction to cause the elongation of the molten conductive material 804.

The elongation of the molten conductive material 804 is an optional step depending on whether the molded underfill is desired or required. Sometimes, it is possible to use the molded underfill without the elongation of the molten conductive material 804 because the molding pressure is sufficient to fill the space between the integrated circuit 104 and the substrate 102 without forming voids or traps.

Other times, as the bond pitch decreases, the molded underfill requires the elongation of the molten conductive material 804 to fill the space between the integrated circuit 104 and the substrate 102 without forming voids or traps. At other times, the molded underfill cannot fill the space between the integrated circuit 104 and the substrate 102 without forming voids or traps even without the elongation of the molten conductive material 804.

It has been found that sometimes, a capillary underfill can be used to fill the space between the integrated circuit 104 and the substrate 102 without forming voids or traps without the elongation of the molten conductive material 804. The capillary underfill is an underfill that fills the space between an integrated circuit and a substrate by a capillary action without forming voids or traps.

However, as a distance between the integrated circuit 104 and the substrate 102 becomes extremely small, it has been found that both the elongation of the molten conductive material 804 and the capillary underfill are required.

It has been found that the embodiments of the present invention allow an adjustment of the bonding height by pulling the bonding head 704 up to control a z-axis position and control solder elongation to allow a capillary underfill (CUF) or molded underfill (MUF) to be used in an integrated circuit package as desired or required.

It has also been found that the embodiments of the present invention could be used with below 10 um elongation amounts for 17 um solder cap height so about 60% of solder cap height is suitable for elongation amounts.

Referring now to FIG. 11, therein is shown the structure of FIG. 10 in a bonding head cooling step 1102. Cooling of the bonding head 704 allows the internal interconnects 114 to solidify.

Referring now to FIG. 12, therein is shown the structure of FIG. 11 in a bonding head removal step 1202. The bonding head 704 of FIG. 7 is removed or detached from the integrated circuit 104.

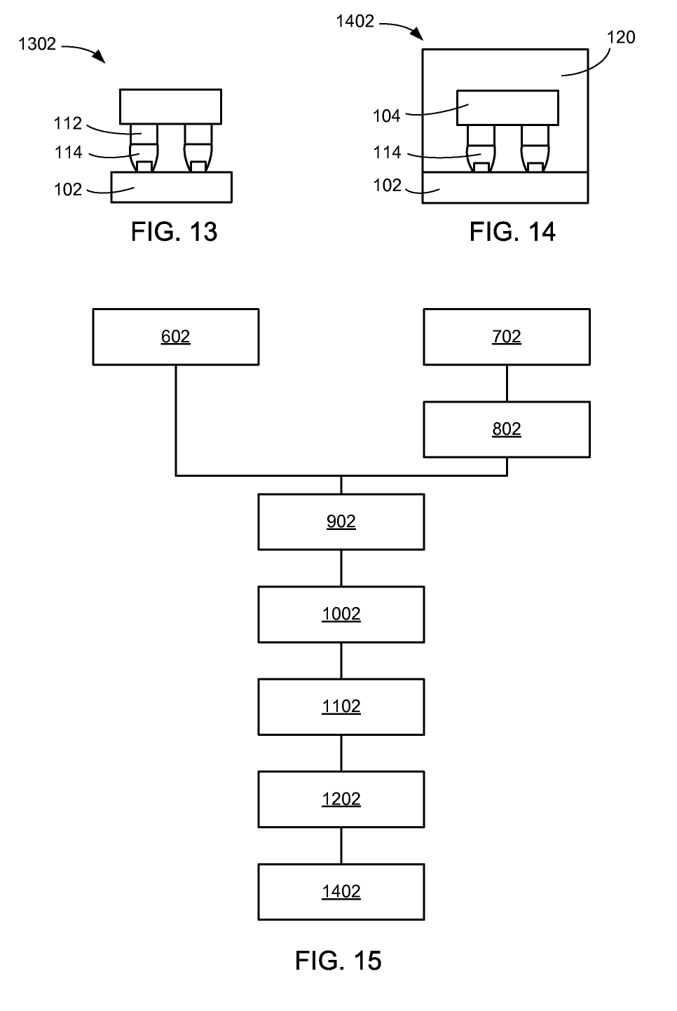

Referring now to FIG. 13, therein is shown the structure of FIG. 12 in a de-fluxing step 1302. When a non-cleaning solder is not used for the internal interconnects 114, this step is required to remove the residual flux 906 of FIG. 9.

It has been found that in some embodiments of the present invention, the non-cleaning solder is critical because a bump pitch of the internal interconnects 114 or the device connectors 112 becomes so small that the internal interconnects 114 or the device connectors 112 are fragile and break or damage the substrate 102 during a de-fluxing or cleaning step.

Referring now to FIG. 14, therein is shown the structure of FIG. 13 in an underfilling step 1402. A molded underfill is shown with the encapsulation 120 but a capillary underfill could be used for the underfill 116 of FIG. 1 if a vertical distance between the integrated circuit 104 and the substrate 102 is too small for the molded underfill to fill the distance without forming voids. The encapsulation 120 is over the internal interconnects 114 and the substrate 102.

Referring now to FIG. 15, therein is shown a flow chart of the process flow described above. The process flow includes the depositing flux step 602. The process flow also includes the die pickup step 702 followed by the bonding head heating step 802. The depositing flux step 602 occurs in parallel with the die pickup step 702 and the bonding head heating step 802.

After the depositing flux step 602 and the bonding head heating step 802, the bonding step 902 is performed. Then, the elongation step 1002 is performed. After that, the process flow continues with the bonding head cooling step 1102 followed by the bonding head removal step 1202.

After the bonding head removal step 1202, the de-fluxing step 1302 of FIG. 13 can be performed if the non-cleaning solder is not used for the internal interconnects 114 of FIG. 1. After the bonding head removal step 1202 or the de-fluxing step 1302, the process flow completes with the underfilling step 1402.

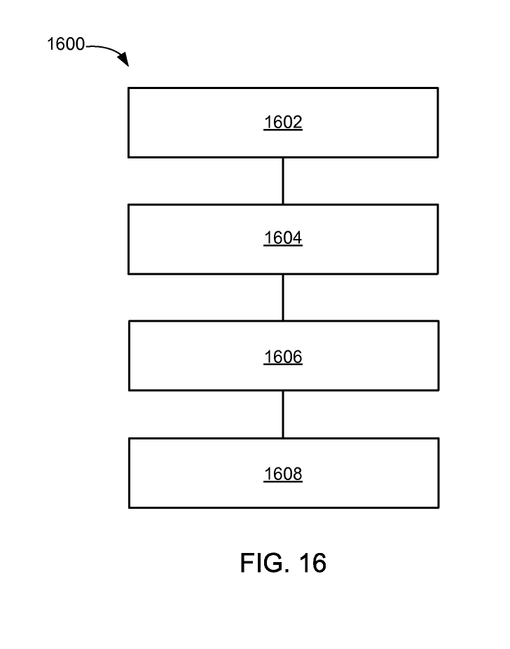

Referring now to FIG. 16, therein is shown a flow chart of a method 1600 of manufacture of an integrated circuit packaging system in a further embodiment of the present invention. The method 1600 includes: providing an integrated circuit in a block 1602; providing a substrate having a substrate contact in a block 1604; forming an internal interconnect between the substrate and the integrated circuit, the internal interconnect is a no-reflow connection directly on the substrate contact and the integrated circuit in a block 1606; and forming an encapsulation over the internal interconnect in a block 1608.

Thus, it has been discovered that the method of manufacture of the integrated circuit packaging system of the embodiments of the present invention furnishes important and heretofore unknown and unavailable solutions, capabilities, and functional aspects for an integrated circuit packaging system with no-reflow solder connection.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems fully compatible with conventional manufacturing methods or processes and technologies.

Another important aspect of the embodiments of the present invention is that it valuably supports and services the historical trend of reducing costs, simplifying systems, and increasing performance.

These and other valuable aspects of the embodiments of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing an integrated circuit;
providing a substrate having a substrate contact;
forming an internal interconnect between the substrate and the integrated circuit, the internal interconnect is a no-reflow connection directly on the substrate contact and the integrated circuit; and
forming an encapsulation over the internal interconnect.

2. The method as claimed in claim 1 wherein forming the internal interconnect includes forming the internal interconnect directly on a substrate contact top side of the substrate contact and a device connector of the integrated circuit.

3. The method as claimed in claim 1 wherein forming the internal interconnect includes forming the internal interconnect only directly on a substrate contact top side of the substrate contact and a device connector of the integrated circuit.

4. The method as claimed in claim 1 wherein forming the internal interconnect includes forming the internal interconnect vertically elongated.

5. The method as claimed in claim 1 further comprising forming an underfill between the substrate and the integrated circuit.

6. A method of manufacture of an integrated circuit packaging system comprising:
providing an integrated circuit;
providing a substrate having a substrate contact;
forming an internal interconnect between the substrate and the integrated circuit, the internal interconnect is a no-reflow connection directly on the substrate contact and the integrated circuit; and
forming an encapsulation over the internal interconnect and the substrate.

7. The method as claimed in claim 6 wherein forming the internal interconnect includes forming the internal interconnect directly on a contact non-horizontal side of the substrate contact, a substrate contact top side of the substrate contact, and a device connector of the integrated circuit.

8. The method as claimed in claim 6 wherein forming the internal interconnect includes forming the internal interconnect only directly on a substrate contact top side of the substrate contact and a device connector of the integrated circuit, wherein the substrate contact is completely within the substrate.

9. The method as claimed in claim 6 wherein forming the internal interconnect includes forming the internal interconnect vertically elongated and directly on the substrate contact and an active side of the integrated circuit, the internal interconnect having a concave non-horizontal surface.

10. The method as claimed in claim 6 further comprising forming an underfill between the substrate and the integrated circuit, the underfill covering the internal interconnect.

11. An integrated circuit packaging system comprising:
an integrated circuit;
a substrate having a substrate contact;
an internal interconnect between the substrate and the integrated circuit, the internal interconnect is a no-reflow connection directly on the substrate contact and the integrated circuit; and
an encapsulation over the internal interconnect.

12. The system as claimed in claim 11 wherein the internal interconnect is directly on a substrate contact top side of the substrate contact and a device connector of the integrated circuit.

13. The system as claimed in claim 11 wherein the internal interconnect is only directly on a substrate contact top side of the substrate contact and a device connector of the integrated circuit.

14. The system as claimed in claim 11 wherein the internal interconnect is vertically elongated.

15. The system as claimed in claim 11 further comprising an underfill between the substrate and the integrated circuit.

16. The system as claimed in claim 11 wherein the encapsulation is over the substrate.

17. The system as claimed in claim 16 wherein the internal interconnect is directly on a contact non-horizontal side of the substrate contact, a substrate contact top side of the substrate contact, and a device connector of the integrated circuit.

18. The system as claimed in claim 16 wherein the internal interconnect is only directly on a substrate contact top side of the substrate contact and a device connector of the integrated circuit, wherein the substrate contact is completely within the substrate.

19. The system as claimed in claim 16 wherein the internal interconnect is vertically elongated and directly on the substrate contact and an active side of the integrated circuit, the internal interconnect having a concave non-horizontal surface.

20. The system as claimed in claim 16 further comprising an underfill between the substrate and the integrated circuit, the underfill covering the internal interconnect.
